(19) United States
(12) Patent Application Publication
(10) Pub. No.: US 2024/0079538 A1
(43) Pub. Date: Mar. 7, 2024

(54) LIGHT-EMITTING DEVICE AND METHOD FOR MANUFACTURING LIGHT-EMITTING DEVICE

(71) Applicant: NIKKISO CO., LTD., Tokyo (JP)

(72) Inventor: Kazuyoshi SAKURAGI, Hakusan-shi, Ishikawa (JP)

(73) Assignee: NIKKISO CO., LTD., Tokyo (JP)

(21) Appl. No.: 18/455,755

(22) Filed: Aug. 25, 2023

(30) Foreign Application Priority Data
Aug. 26, 2022 (JP) 2022-134978

(51) Int. Cl. H01L 33/58

(52) U.S. Cl. CPC H01L 33/58; H01L 2933/0058

(57) ABSTRACT

A light-emitting device 1 includes a semiconductor light-emitting element 2 emitting ultraviolet light, a first substrate 5 on which the semiconductor light-emitting element 2 is mounted, a second substrate 6 which is arranged on a side of the first substrate 5 opposite to the semiconductor light-emitting element 2 and on which the first substrate 5 is mounted, and an optical member 7 adhered using a resin adhesive 8 to a surface 61 of the second substrate 6 on the first substrate 5 side.

### CROSS-REFERENCE TO RELATED APPLICATIONS

The present application is based on Japanese patent application No. 2022-134978 filed on Aug. 26, 2022, the entire contents of which are incorporated herein by reference.

### TECHNICAL FIELD

The present invention relates to a light-emitting device and a method for manufacturing a light-emitting device.

### BACKGROUND OF THE INVENTION

Patent Literature 1 discloses a light-emitting device that has a light-emitting element emitting ultraviolet light, a substrate on which the light-emitting element is mounted, and a lens adhered to a mounting surface of the substrate using an adhesive layer.

Citation List Patent Literature 1: JP2022-48933A

### SUMMARY OF THE INVENTION

To fix optical members such as lens, there is sometimes a desire to use resin adhesives from the viewpoint of improving productivity, etc. However, resin adhesives may degrade by exposure to ultraviolet light emitted by light-emitting elements.

The invention was made in view of such circumstances and it is an object of the invention to provide a light-emitting device in which degradation of a resin adhesive can be suppressed, and a method for manufacturing such a light-emitting device.

To achieve the object described above, the invention provides a light-emitting device, comprising:
a semiconductor light-emitting element emitting ultraviolet light;
a first substrate on which the semiconductor light-emitting element is mounted;
a second substrate which is arranged on a side of the first substrate opposite to the semiconductor light-emitting element and on which the first substrate is mounted; and
an optical member adhered using a resin adhesive to a surface of the second substrate on the first substrate side.

To achieve the object described above, the invention also provides a method for manufacturing a light-emitting device, comprising:
assembling a semiconductor light-emitting element emitting ultraviolet light, a first substrate on which the semiconductor light-emitting element is mounted, and a second substrate which is arranged on a side of the first substrate opposite to the semiconductor light-emitting element and on which the first substrate is mounted; and
adhering an optical member using a resin adhesive to a surface of the second substrate on the first substrate side.

### Advantageous Effects of the Invention

According to the invention, it is possible to provide a light-emitting device in which degradation of a resin adhesive can be suppressed, and a method for manufacturing such a light-emitting device.

### BRIEF DESCRIPTION OF DRAWINGS

FIG. 1 is a plan view showing a light-emitting device in the first embodiment.

FIG. 2 is a cross-sectional view taken along line II-II in FIG. 1 and viewed in an arrow direction.

FIG. 3 is an enlarged view showing a portion of FIG. 2.

FIG. 4 is a plan view showing the light-emitting device in the second embodiment.

FIG. 5 is a cross-sectional view taken along line V-V in FIG. 4 and viewed in an arrow direction.

FIG. 6 is an enlarged view showing a portion of FIG. 5.

### DETAILED DESCRIPTION OF THE INVENTION

### First Embodiment

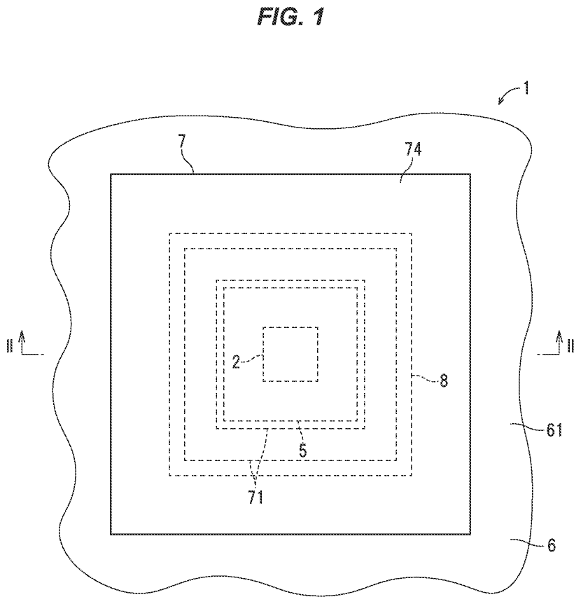

The first embodiment of the invention will be described in reference to FIGS. 1 to 3. The embodiment below is described as a preferred illustrative example for implementing the invention. Although some part of the embodiment specifically illustrates various technically preferable matters, the technical scope of the invention is not limited to such specific aspects.

Light-Emitting Device 1

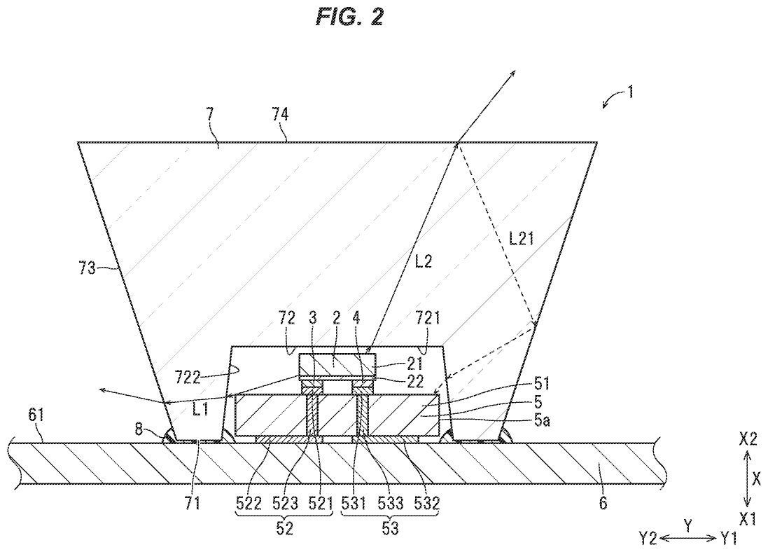

FIG. 1 is a plan view showing a light-emitting device 1 in the first embodiment. FIG. 2 is a cross-sectional view taken along line II-II in FIG. 1 and viewed in an arrow direction.

The light-emitting device 1 in the first embodiment includes a semiconductor light-emitting element 2 composed of, e.g., a light-emitting diode (LED) or a semiconductor laser (LD: laser diode). The semiconductor light-emitting element 2 emits ultraviolet light. The light-emitting device 1 in the first embodiment includes the semiconductor light-emitting element 2, a p-side element electrode 3, an n-side element electrode 4, a first substrate 5, a second substrate 6, an optical member 7 and an adhesive 8.

As shown in FIG. 1, the semiconductor light-emitting element 2 has a quadrangular shape (a substantially square shape in the first embodiment) in plan view. As shown in FIG. 2, the semiconductor light-emitting element 2 includes a transparent substrate 21 and a semiconductor stack structure 22 formed on a growth surface of the transparent substrate 21. Hereinafter, a direction of stacking the transparent substrate 21 and the semiconductor stack structure 22 (e.g., an up-and-down direction in FIG. 2) is referred to as “the up-and-down direction X”. In this regard, the terms “up/upper” and “down/lower” are used for the sake of convenience and do not limit the posture of the light-emitting device 1 with respect to the vertical direction when, e.g., the light-emitting device 1 is in use.

The transparent substrate 21 can be, e.g., a sapphire (Al₂O₃) substrate or an aluminum nitride (AlN) substrate, etc., and has properties that allow transmission of ultraviolet light emitted by a light-emitting layer of the semiconductor stack structure 22. The semiconductor stack structure 22 is formed on the growth surface which is one of principal surfaces of the transparent substrate 21.

As semiconductors constituting the semiconductor stack structure 22, it is possible to use, e.g., binary to quaternary group III nitride semiconductors expressed by AlₓGa_{y}In_{1-x-y}N (0≤x≤1, 0≤y≤1, 0≤x+y≤1). In the first embodiment, each layer of the semiconductor stack structure 22 is formed of an Al_{z}Ga_{1-z}N (0≤z≤1)-based semiconductor not containing indium.

The semiconductor stack structure 22 includes at least an n-type semiconductor layer, the light-emitting layer and a p-type semiconductor layer in this order from the transparent substrate 21 side. In the light-emitting layer, electrons supplied from the n-type semiconductor layer recombine with holes supplied from the p-type semiconductor layer, resulting in light emission. The light-emitting layer emits ultraviolet light at a central wavelength of not less than 200 nm and not more than 365 nm, preferably deep ultraviolet light at a central wavelength of not more than 280 nm. In FIG. 2, a general shape of the semiconductor stack structure 22 is schematically shown and boundaries between the layers of the semiconductor stack structure 22 are not shown.

The semiconductor stack structure 22 can be formed by epitaxial growth. Epitaxial growth can be performed by the Metal Organic Chemical Vapor Deposition (MOCVD) method, the Molecular Beam Epitaxy (MBE) method or the Hydride Vapor Phase Epitaxy (HVPE) method, etc.

The p-side element electrode 3 is connected to the p-type semiconductor layer of the semiconductor stack structure 22 on the opposite side to the transparent substrate 21. The n-side element electrode 4 is connected to the n-type semiconductor layer of the semiconductor stack structure 22 on the opposite side to the transparent substrate 21. Although it is not shown in the drawing, the light-emitting layer and the p-type semiconductor layer are partially removed by etching, etc., to expose the n-type semiconductor layer on the side opposite to the transparent substrate 21, and the n-side element electrode 4 is connected to the exposed surface of the n-type semiconductor layer which is formed in such a way.

The semiconductor light-emitting element 2 is flip-chip mounted on the first substrate 5 in such a manner that the transparent substrate 21 is located on a side opposite to the first substrate 5 with the semiconductor stack structure 22 therebetween. The semiconductor light-emitting element 2 is connected at the p-side element electrode 3 and the n-side element electrode 4 to the first substrate 5 via electrical connection portions (not shown) such as bumps. Hereinafter, the first substrate 5 side of the semiconductor light-emitting element 2 is referred to as a lower side X1, and the opposite side is referred to as an upper side X2.

In the first embodiment, the first substrate 5 is a component also called a submount, and the structure in which the first substrate 5 and the semiconductor light-emitting element 2 are connected is also called a chip on submount (CoS). In plan view, the first substrate 5 has a rectangular shape (a substantially square shape in the first embodiment) and the semiconductor light-emitting element 2 is arranged at the center of the first substrate 5, as shown in FIG. 1.

The first substrate 5 is formed in a flat plate shape. As shown in FIG. 2, the first substrate 5 has a base 51, a p-side conductive portion 52 and an n-side conductive portion 53. The base 51 is formed in a quadrangular (substantially square in the first embodiment) plate shape, and is made of an electrically insulating material.

The p-side conductive portion 52 has a p-side upper-surface electrode 521 formed on an upper surface of the base 51, a p-side lower-surface electrode 522 formed on a lower surface of the base 51, and a p-side via 523 connecting therebetween in a thickness direction of the first substrate 5. The n-side conductive portion 53 has an n-side upper-surface electrode 531 formed on the upper surface of the base 51, an n-side lower-surface electrode 532 formed on the lower surface of the base 51, and an n-side via 533 connecting therebetween in the thickness direction of the first substrate 5. The p-side conductive portion 52 and the n-side conductive portion 53 are electrically isolated from each other. The p-side upper-surface electrode 521 is connected to the p-side element electrode 3, and the n-side upper-surface electrode 531 is connected to the n-side element electrode 4. Constant-voltage elements such as Zener diodes may be mounted on the A-side upper-surface electrode 521 and the n-side upper-surface electrode 531. The p-side lower-surface electrode 522 and the n-side lower-surface electrode 532 are connected to the second substrate 6.

The second substrate 6 is formed in a flat plate shape. The second substrate 6 is larger than the first substrate 5 in plan view. The second substrate 6 can be, e.g., a printed circuit board (PCB) and has a wiring pattern (not shown) that is connected to the p-side lower-surface electrode 522 and the n-side lower-surface electrode 532. As shown in FIG. 2, the optical member 7 is provided on an upper surface 61 of the second substrate 6 so as to cover the semiconductor light-emitting element 2 and the first substrate 5.

The optical member 7 is a member intended to, e.g., reflect, transmit or refract light and is, e.g., a lens, a reflector, or a lid, etc. The optical member 7 in the first embodiment is a TIR (Total Internal Reflection) lens that collects light emitted from the semiconductor light-emitting element 2 by guiding the light to the inside and also totally reflecting the light at a side surface 73 toward a light extraction surface 74. As an example, the optical member 7 can be made of quartz glass, borosilicate glass, low melting-point glass, silicone resin, or epoxy resin, etc. As an example, the optical member 7 can be molded using plural molds which are designed to be removed in the up-and-down direction X.

The outer shape of the optical member 7 is a truncated quadrangular pyramid shape that tapers to the bottom. As shown in FIG. 2, a surface of the optical member 7 has a bottom surface 71, a recessed surface 72, the side surface 73 and the light extraction surface 74. The bottom surface 71 is a surface of the optical member 7 facing the second substrate 6 and has a quadrangular ring shape as shown in FIG. 1. As shown in FIG. 2, the bottom surface 71 of the optical member 7 is adhered to the second substrate 6 using the adhesive 8.

As shown in FIG. 2, the recessed surface 72 is recessed from the bottom surface 71 toward the upper side X2 and covers the semiconductor light-emitting element 2 and the first substrate 5. The concave surface 72 serves as an incident surface that guides the light emitted from the semiconductor light-emitting element 2 to the inner side of the optical member 7. The recessed surface 72 has a recess bottom surface 721 having a quadrangular shape (a substantially square shape in the first embodiment) and a recess side surface 722 having a quadrangular cylindrical shape and extending from four sides of the recess bottom surface 721 toward the lower side X1. Although the recess bottom surface 721 is formed in a flat surface shape orthogonal to the up-and-down direction X in the first embodiment, it is not limited thereto, and the recess bottom surface 721 can be, e.g., a curved surface convex toward the lower side X1.

The recess side surface 722 is formed in close proximity to and along a side surface 5a of the first substrate 5. A slight gap is formed between the recess side surface 722 and the first substrate 5 to allow insertion of the first substrate 5 into the recessed surface 72. When viewed in a cross section of the light-emitting device 1 parallel to the up-and-down direction X, the recess side surface 722 is inclined inward in an orthogonal direction Y orthogonal to the up-and-down direction X (i.e., toward the space in the recessed surface 72) so as to narrow toward the upper side X2. Hereafter, when simply referred to as “when viewed in a cross section”, it means a cross-sectional view of the light-emitting device 1 parallel to the up-and-down direction X, unless otherwise specified.

The side surface 73 has a truncated quadrangular pyramid surface shape that tapers to the bottom. When viewed in a cross section, the side surface 73 is inclined toward the semiconductor light-emitting element 2 in the orthogonal direction Y so as to narrow toward the lower side X1. In the first embodiment, an inclination angle of the side surface 73 relative to the up-and-down direction X is larger than an inclination angle of the recess side surface 722 relative to the up-and-down direction X. Although the details will be described later, the above-described inclinations of the recess side surface 722 and the side surface 73 relative to the up-and-down direction X suppress an occurrence in which the light emitted from the semiconductor light-emitting element 2 heads to the adhesive 8, and as a result, degradation of the adhesive 8 by exposure to ultraviolet light is suppressed.

The light-extracting surface 74 is a surface facing the side opposite to the second substrate 6 and has a quadrangular shape (a substantially square shape in the first embodiment). Although the light extraction surface 74 is formed in a flat surface shape orthogonal to the up-and-down direction X in the first embodiment, it is not limited thereto, and it is possible to adopt various shapes according to the purpose, such as to improve light extraction efficiency or to collimate light to be extracted. However, when the light extraction surface 74 has a shape other than the flat surface, the image of the semiconductor light-emitting element 2 through the light extraction surface 74 is distorted when assembling the optical member 7 to the semiconductor light-emitting element 2 and the first substrate 5 and this distortion of the image may make assembly difficult, hence, the light extraction surface 74 is preferably a flat surface from the viewpoint of improving ease of assembly. The light extraction surface 74 is a surface from which light reflected at the side surface 73 is extracted.

The adhesive 8 adheres the bottom surface 71 of the optical member 7 to the upper surface 61 of the second substrate 6. When adhering the bottom surface 71 of the optical member 7 to the upper surface 61 of the second substrate 6 with the adhesive 8, the adhesive 8 in a flowable state is applied to the bottom surface 71 of the optical member 7 or the upper surface 61 of the second substrate 6, the bottom surface 71 of the optical member 7 is pressed toward the upper surface 61 of the second substrate 6, and the adhesive 8 is then cured. At this time, depending on the amount of the adhesive 8, a portion of the adhesive 8 may slightly rise along the side surface 73 and the recess side surface 722 of the optical member 7.

The adhesive 8 is made of, e.g., a silicone resin, a fluoropolymer, or an epoxy resin, etc. In the first embodiment, the adhesive 8 is located on the upper surface 61 of the second substrate 6 as described above and is thus not required to transmit ultraviolet light emitted from the semiconductor light-emitting element 2. Therefore, an ultraviolet absorber which absorbs ultraviolet rays, such as carbon black, can be mixed to the adhesive 8 to increase the resistance of the adhesive to ultraviolet light. Silicone resins, fluoropolymers and epoxy resins, etc., have relatively high resistance to ultraviolet light, but their binders or curing agents, etc., contain covalent bonds having a bond energy smaller than the energy of ultraviolet light. Therefore, if the adhesive 8 is exposed to strong ultraviolet light for a long period of time, degradation of the adhesive 8 such as coming off, cracking or discoloration may occur. The adhesive 8 is likely to degrade at a significant rate particularly when the semiconductor light-emitting element 2 emits deep ultraviolet light.

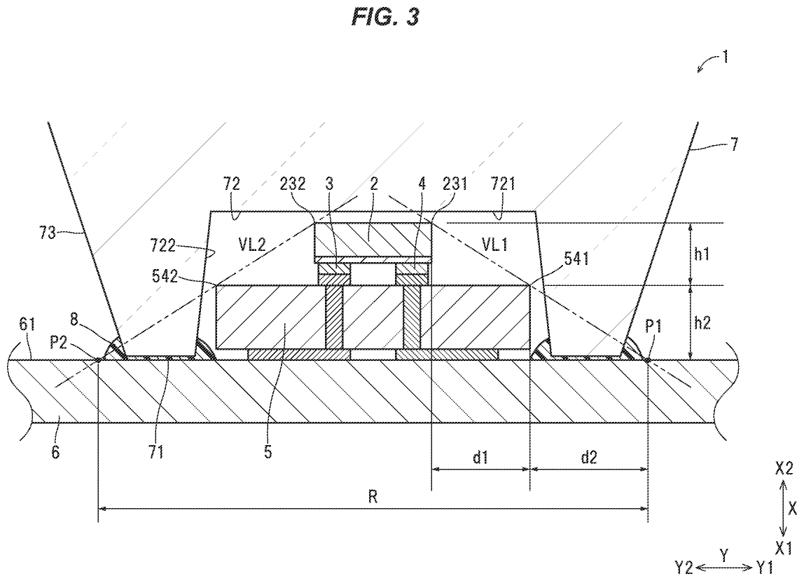

Thus, in the light-emitting device 1 of the first embodiment, the adhesive 8 is arranged on the upper surface 61 of the second substrate 6, not on the first substrate 5, so that the adhesive 8 is less likely to be exposed to the ultraviolet light emitted from the semiconductor light-emitting element 2. In addition, particularly in the first embodiment, at least a portion of the adhesive 8 is arranged in a region R of the upper surface 61 of the second substrate 6 (see FIG. 3 which will be described later) where the first substrate 5 creates a shadow by blocking the light emitted from the semiconductor light-emitting element 2 in the state in which the optical member 7 is not attached to the light-emitting device 1. Next, the region R will be described in detail.

FIG. 3 is an enlarged view showing a portion of FIG. 2. A first-side element end portion 231, a first-side substrate end portion 541, a first-side imaginary straight line VL1, a first-side intersection point P1, a second-side element end portion 232, a second-side substrate end portion 542, a second-side imaginary straight line VL2 and a second-side intersection point P2, which are described below, are defined when viewed in a cross section. The first-side element end portion 231 is an end portion of the semiconductor light-emitting element 2 located on the upper side X2 as well as on a first side Y1 that is one side in the orthogonal direction Y. The first-side substrate end portion 541 is an end portion of the first substrate 5 located on the upper side X2 as well as on the first side Y1. The first-side imaginary straight line VL1 is an imaginary straight line connecting the first-side element end portion 231 and the first-side substrate end portion 541. The first-side intersection point P1 is a point where the first-side imaginary straight line VL1 intersects the upper surface 61 of the second substrate 6. The second-side element end portion 232 is an end portion of the semiconductor light-emitting element 2 located on the upper side X2 as well as on a second side Y2 that is opposite to the first side Y1 in the orthogonal direction Y. The second-side substrate end portion 542 is an end portion of the first substrate 5 located on the upper side X2 as well as on the second side Y2. The second-side imaginary straight line VL2 is an imaginary straight line connecting the second-side element end portion 232 and the second-side substrate end portion 542. The second-side intersection point P2 is a point where the second-side imaginary straight line VL2 intersects the upper surface 61 of the second substrate 6.

When defined as above, at least a portion of the adhesive 8 is arranged in the region R between the first-side intersection point P1 and the second-side intersection point P2 on the upper surface 61 of the second substrate 6. This region R is the above-mentioned region of the upper surface 61 of the second substrate 6 where the first substrate 5 creates a shadow by blocking the light emitted from the semiconductor light-emitting element 2 in the state in which the optical member 7 is not attached to the light-emitting device 1.

Next, how to calculate a length d2, which is the length of the portion of the upper surface 61 of the second substrate 6 exposed from the first substrate 5 and constitutes the region R, will be described with reference to the cross-sectional view in FIG. 3. Firstly, a portion of the light-emitting device 1 on the first side Y1 when viewed in a cross section will be examined. A length in the up-and-down direction X between the first-side element end portion 231 and the first-side substrate end portion 541 is defined as h1 [mm], and a length in the up-and-down direction X between the first-side substrate end portion 541 and the upper surface 61 of the second substrate 6 is defined as h2 [mm]. In addition, a length in the orthogonal direction Y between the first-side element end portion 231 and the first-side substrate end portion 541 is defined as d1 [mm], and a length in the orthogonal direction Y between the first-side substrate end portion 541 and the first-side intersection point P1 is defined as d2 [mm]. In this case, the length d2 (i.e., a width of the portion of the upper surface 61 of the second substrate 6 which is exposed from the first substrate 5 and constitutes the region R) is expressed by the following equation (1).

$$d 2 = \frac{( h 1 + h 2 ) \cdot d 1}{h 1} - d 1 \qquad ( 1 )$$

As understood from the equation (1), once the lengths h1, h2 and d1 are fixed, it is possible to calculate the length d2 of an area which is the portion of the upper surface 61 of the second substrate 6 exposed on the upper side X2 from the first substrate 5 and where the first substrate 5 creates a shadow by blocking the light emitted from the semiconductor light-emitting element 2. By designing the shape of the optical member 7 based on the calculated length d2, it is possible to arrange the adhesive 8 in the shadow area. The same applies to a portion of the light-emitting device 1 on the second side Y2 when viewed in a cross section. The same applies to cross sections of the light-emitting device 1 parallel to the up-and-down direction X, other than the cross section shown in FIGS. 2 and 3.

A width of the adhesive 8 when viewed in a cross section is preferably not less than 1 mm. In this case, adhesion between the optical member 7 and the second substrate 6 is improved and productivity is enhanced. Thus, the lengths h1, h2 and d1 are preferably designed so that the length d2 is not less than 1 mm, and the width of the adhesive 8 is not less than 1 mm. In addition, a width of the bottom surface 71 of the optical member 7 when viewed in a cross section is also preferably not less than 1 mm.

The adhesive 8 may be arranged entirely outside the region R on the upper surface 61 of the second substrate 6. Also in this case, it is possible to suppress degradation of the adhesive 8 as compared to when, e.g., the optical member 7 is directly attached to the semiconductor light-emitting element 2 or the first substrate 5 since the adhesive 8 is arranged at a position optically far from the semiconductor light-emitting element 2. In addition, in the light-emitting device 1 including the optical member 7, the shadow region on the upper surface 61 of the second substrate 6 may be wider than the region R. This is because light is refracted by the inclinations of the recess side surface 722 and the side surface 73, as described below.

Functions of the inclination of the recess side surface 722 and the inclination of the side surface 73

Next, an example of the function of having the inclination of the recess side surface 722 and the inclination of the side surface 73 as described above will be described.

FIG. 2 schematically shows an example of a path of light L1 which is emitted diagonally downward from the semiconductor light-emitting element 2. By the inclination of the recess side surface 722, the light L1 is refracted to be closer to the orthogonal direction Y at the time of entering the optical member 7 from the recess side surface 722. This suppresses an occurrence in which the light L1, which enters the optical member 7 from the recess side surface 722, heads to the adhesive 8. To obtain this effect further effectively, an inclination angle of the recess side surface 722 relative to the up-and-down direction X is preferably, e.g., not less than 5°.

Then, the light L1 is refracted diagonally upward at the time of exiting from the side surface 73 to the outside of the optical member 7. That is, the light L1 changes the direction so as to be away from the adhesive 8 due to refraction at the time of entering the optical member 7 from the recess side surface 722 and refraction at the time of exiting from the side surface 73 to the outside of the optical member 7. This suppresses an occurrence in which the light L1, which is emitted obliquely downward from the semiconductor light emitting element 2, reaches the adhesive 8.

FIG. 2 also schematically shows an example of a path of light L2 which is emitted diagonally upward from the semiconductor light-emitting element 2. The light L2 is emitted diagonally upward from the semiconductor light-emitting element 2, passes through the recess bottom surface 721 and travels inside the optical member 7. Most of the light L2 then exits from the light extraction surface 74, but a portion of the light L2, which is light L21 indicated by the broken line, is reflected at the light extraction surface 74.

The light L21 reflected at the light extraction surface 74 heads diagonally downward and is reflected at the side surface 73. At this time, due to the inclination of the side surface 73, the direction of the light L21 after being reflected at the side surface 73 becomes closer to parallel to the orthogonal direction Y than before being reflected. That is, the inclination of the side surface 73 suppresses an occurrence in which the light L21 heads to the adhesive 8. The light L21 is then guided from the recess side surface 722 to the space in the recessed surface 72. As described above, the inclinations of the recess side surface 722 and the side surface 73 serve to suppress an occurrence in which ultraviolet light is guided toward the adhesive 8.

Method for Manufacturing Light-Emitting Device 1

Next, an example of a method for manufacturing the light-emitting element 1 in the first embodiment will be described.

Firstly, the semiconductor light-emitting element 2, the first substrate 5 and the second substrate 6 are assembled. For example, the semiconductor light-emitting element 2 is mounted on the first substrate 5, and the first substrate 5 is then mounted on the second substrate 6. The assembly order may be such that the first substrate 5 is firstly mounted on the second substrate 6 and the semiconductor light-emitting element 2 is then mounted on the first substrate 5.

Then, the adhesive material 8 in a flowable state is applied to the bottom surface 71 of the optical member 7 over the entire circumference, and the bottom surface 71 of the optical substrate is placed on the upper surface 61 of the second substrate 6 while inserting the semiconductor light-emitting element 2 and the first substrate 5 into the recessed surface 72 of the optical member 7. In the first embodiment, since the semiconductor light-emitting element 2 and the first substrate 5 are fitted into the recessed surface 72 as described above, positioning of the optical member 7 relative to the semiconductor light-emitting element 2 and the first substrate 5 is easily achieved. Alternatively, the adhesive 8 in a flowable state may be applied to the upper surface 61 of the second substrate 6 at a position where the bottom surface 71 of the optical member 7 is to be placed. The adhesive 8 is then cured, thereby obtaining the light-emitting device 1 in the first embodiment.

### Functions and Effects of the First Embodiment

In the light-emitting device 1 of the first embodiment, the optical member 7 is adhered to the upper surface 61 of the second substrate 6 using the resin adhesive 8. Therefore, the resin adhesive 8, which may be degraded by exposure to ultraviolet light, can be located optically far from the semiconductor light-emitting element 2 and degradation of the adhesive 8 can be suppressed.

In addition, when viewed in a cross section of the light-emitting device 1, at least a portion of the adhesive 8 is arranged in the region R between the first-side intersection point P1 and the second-side intersection point P2 on the upper surface 61 of the second substrate 6. This region R is likely to be shadowed since the light emitted from the semiconductor light-emitting element 2 is blocked by the first substrate 5, hence, degradation of the adhesive 8 due to exposure to ultraviolet light is easily suppressed by providing at least a portion of adhesive 8 in the region R.

In addition, the optical member 7 has the bottom surface 71 adhered to the upper surface 61 of the second substrate 6 via the adhesive 8, and the recessed surface 72 which is formed to be recessed from the bottom surface 71, houses the semiconductor light-emitting element 2 and the first substrate 5 and allows entrance of the light emitted from the semiconductor light-emitting element 2. Thus, positioning of the optical member 7 relative to the semiconductor light-emitting element 2 and the first substrate 5 can be easily performed by fitting the semiconductor light-emitting element 2 and the first substrate 5 into the recessed surface 72.

In addition, when viewed in a cross section of the light-emitting device 1, the recessed surface 72 has a portion that extends inwards in the orthogonal direction Y as the distance from the second substrate 6 in the alignment direction increases (the recess side surface 722 in the first embodiment). Thus, light emitted from the semiconductor light-emitting element 2 and introduced into the optical member 7 from said portion is refracted toward the side away from the adhesive 8, thereby further suppressing exposure of the adhesive 8 to ultraviolet light.

In addition, the recessed surface 72 is formed along the side surface 5a of the first substrate 5. This facilitates accurate positioning of the optical member 7 relative to the semiconductor light-emitting element 2 and the first substrate 5.

In addition, the adhesive 8 may contain an ultraviolet absorber that absorbs ultraviolet rays. In the first embodiment, since the adhesive 8 is formed on the upper surface 61 of the second substrate 6 and does not need to transmit ultraviolet light, it is possible to improve resistance of the adhesive to ultraviolet light by mixing the ultraviolet absorber.

In addition, in the method for manufacturing the light-emitting device 1 of the first embodiment, positioning of the optical member 7 relative to the semiconductor light-emitting element 2 and the first substrate 5 is performed by fitting the semiconductor light-emitting element 2 and the first substrate 5 into the recessed surface 72. Therefore, it is possible to easily perform positioning of the optical member 7 relative to the semiconductor light-emitting element 2 and the first substrate 5.

As described above, according to the first embodiment, it is possible to provide a light-emitting device in which degradation of a resin adhesive can be suppressed, and a method for manufacturing such a light-emitting device.

### Second Embodiment

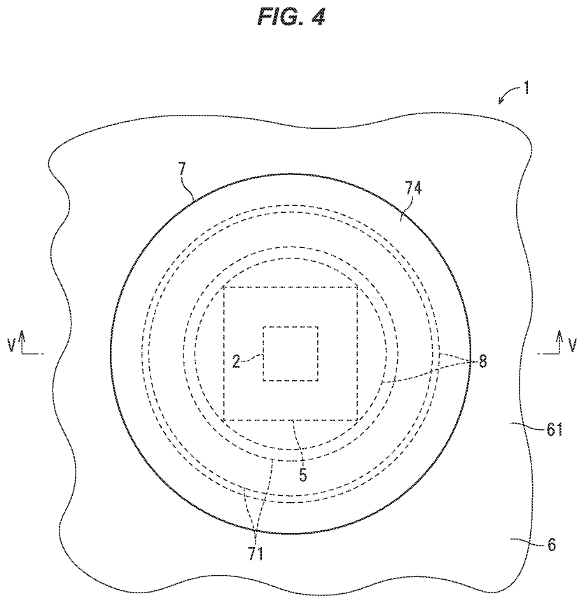

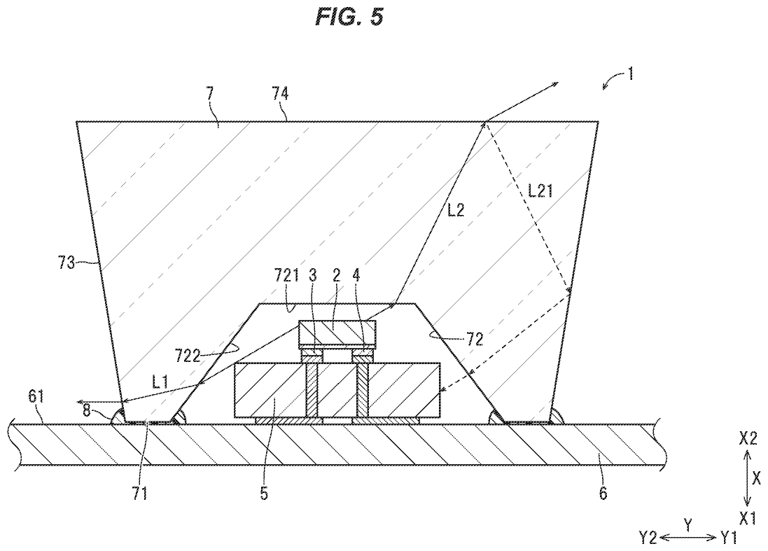

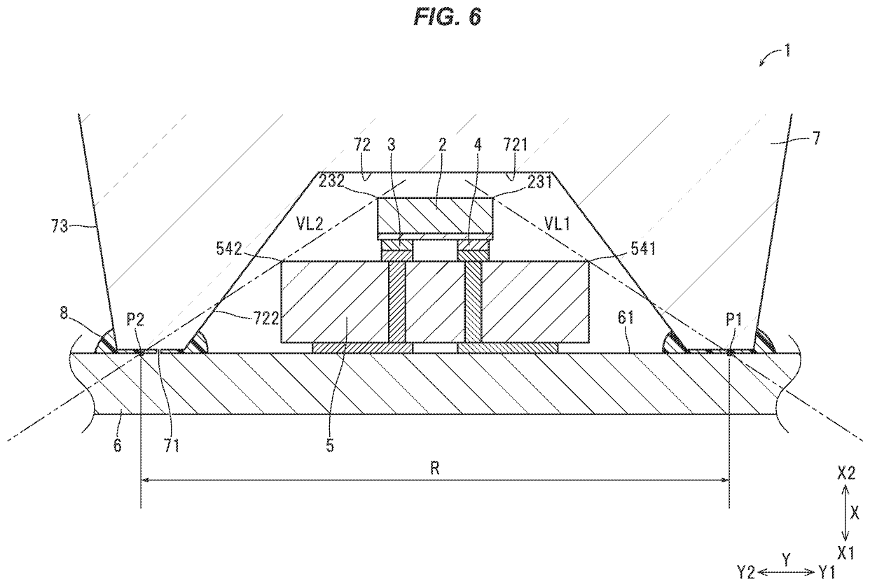

FIG. 4 is a plan view showing the light-emitting device 1 in the second embodiment. FIG. 5 is a cross-sectional view taken along line V-V in FIG. 4 and viewed in an arrow direction. FIG. 6 is an enlarged view showing a portion of FIG. 5.

The second embodiment is an embodiment in which the shape of the optical member 7 is changed with respect to that in the first embodiment. In the second embodiment, the outer shape of the optical member 7 is a truncated conical shape that tapers to the bottom. The bottom surface 71 of the optical member 7 has a circular annular shape. The recess bottom surface 721 has a circular shape. The recess side surface 722 is formed in a truncated conical side surface shape whose diameter increases toward the lower side X1. The recess side surface 722 is formed in close proximity to each of four corners of the first substrate 5. Thus, positioning of the optical member 7 relative to the semiconductor light-emitting element 2 is easily achieved when the semiconductor light-emitting element 2 and the first substrate 5 are inserted into the recessed surface 72. The side surface 73 is formed in a truncated conical side surface shape whose diameter decreases toward the lower side X1. In the second embodiment, the inclination angle of the side surface 73 relative to the up-and-down direction X is smaller than the inclination angle of the recess side surface 722 relative to the up-and-down direction X.

Also in the second embodiment, at least a portion of the adhesive 8 is arranged in the region R between the first-side intersection point P1 and the second-side intersection point P2 on the upper surface 61 of the second substrate 6, as shown in FIG. 6.

The other configurations are the same as in the first embodiment. Among the reference numerals used in the second embodiment onwards, the same reference numerals as those used in the already-described embodiment indicate the same constituent elements, etc., as those in the already-described embodiment, unless otherwise specified.

### Functions and Effects of the Second Embodiment

The second embodiment also has the same functions and effects as those in the first embodiment.

Modifications

Although the recess side surface 722 is an inclined surface (i.e., straight in a cross section) in the first and second embodiments, it is not limited thereto. The recess side surface 722 may be a curved surface. In this case, the recess side surface 722 when viewed in a cross section is preferably formed to extend inward in the orthogonal direction Y so as to narrow toward the upper side X2.

In addition, the recessed surface 72 may be formed in a dome shape in which the recess side surface 722 and the recess bottom surface 721 are smoothly connected. In addition, a corner between the recess side surface 722 and the bottom surface 71 or a corner between the bottom surface 71 and the side surface 73 may be curved.

In addition, although the side surface 73 of the optical member 7 is an inclined surface (i.e., straight in a cross section), it is not limited thereto. The side surface 73 may be a curved surface. In this case, the side surface 73 may be formed so that, e.g., the optical member 7 constitutes a compound parabolic concentrator (CPC).

In addition, although the example in which the optical member 7 is a TIR lens has been described in the first and second embodiments, it is not limited thereto. The optical member 7 may be another lens or may be a member other than a lens (e.g., a metal reflector, etc.).

In addition, although the first substrate 5 and the second substrate 6 which have conductive portions (i.e., the p-side conductive portion 52 and the n-side conductive portion 53) have been described in the first and second embodiments, it is not limited thereto. The first substrate 5 and the second substrate 6 may not have conductive portions.

### Summary of the Embodiments

Technical ideas understood from the embodiments will be described below citing the reference signs, etc., used for the embodiments. However, each reference sign, etc., described below is not intended to limit the constituent elements in the claims to the members, etc., specifically described in the embodiments.

The first feature of the invention is a light-emitting device 1, including: a semiconductor light-emitting element 2 emitting ultraviolet light; a first substrate 5 on which the semiconductor light-emitting element 2 is mounted; a second substrate which is arranged on a side of the first substrate opposite to the semiconductor light-emitting element and on which the first substrate 5 is mounted; and an optical member 7 adhered using a resin adhesive 8 to a surface 61 of the second substrate 6 on the first substrate 5 side.

It is thereby possible to suppress degradation of the resin adhesive 8.

The second feature of the invention is that, in the first feature, when viewed in a cross section parallel to an alignment direction X of the semiconductor light-emitting element 2, the first substrate 5 and the second substrate 6, at least a portion of the adhesive 8 is arranged in a region R between a first-side intersection point P1 and a second-side intersection point P2 on the surface 61 of the second substrate 6 on the first substrate 5 side, where an end portion of the semiconductor light-emitting element 2 on the side opposite to the second substrate 6 and also on a first side Y1, which is one side in an orthogonal direction Y orthogonal to the alignment direction X, is defined as a first-side element end portion 231, an end portion of the first substrate 5 on the side opposite to the second substrate 6 and also on the first side Y1 in the orthogonal direction Y is defined as a first-side substrate end portion 541, a point at which a first-side imaginary straight line VL1 connecting the first-side element end portion 231 and the first-side substrate end portion 541 intersects the surface 61 of the second substrate 6 on the first substrate 5 side is defined as the first-side intersection point P1, an end portion of the semiconductor light-emitting element 2 on the side opposite to the second substrate 6 and also on a second side Y2, which is opposite to the first side Y1 in the orthogonal direction Y, is defined as a second-side element end portion 232, an end portion of the first substrate 5 on the side opposite to the second substrate 6 and also on the second side Y2 in the orthogonal direction Y is defined as a second-side substrate end portion 542, and a point at which a second-side imaginary straight line VL2 connecting the second-side element end portion 232 and the second-side substrate end portion 542 intersects the surface 61 of the second substrate 6 on the first substrate 5 side is defined as a second-side intersection point P2.

It is thereby possible to suppress degradation of the resin adhesive 8.

The third feature of the invention is that, in the first or second feature, the optical member 7 includes a bottom surface 71 adhered via the adhesive 8 to the surface 61 of the second substrate 6 on the first substrate 5 side, and a recessed surface 72 which is recessed from the bottom surface 71, houses the semiconductor light-emitting element 2 and the first substrate 5 and allows entrance of light emitted from the semiconductor light-emitting element 2.

It is thereby possible to easily perform positioning of the optical member 7 relative to the semiconductor light-emitting element 2 and the first substrate 5.

The fourth feature of the invention is that, in the third feature, when viewed in a cross section parallel to an alignment direction X of the semiconductor light-emitting element 2, the first substrate 5 and the second substrate 6, the recessed surface 72 includes a portion that extends inward in a direction orthogonal to the alignment direction X as a distance from the second substrate 6 in the alignment direction X increases. It is thereby possible to suppress degradation of the resin adhesive 8.

The fifth feature of the invention is that, in the third or fourth feature, the recessed surface 72 is formed along a side surface 5a of the first substrate 5.

It is thereby possible to easily perform positioning of the optical member 7 relative to the semiconductor light-emitting element 2 and the first substrate 5.

The sixth feature of the invention is that, in any one of the first to fifth features, the adhesive 8 includes an ultraviolet absorber that absorbs ultraviolet rays. It is thereby possible to suppress degradation of the resin adhesive 8.

The seventh feature of the invention is a method for manufacturing a light-emitting device 1, including: assembling a semiconductor light-emitting element 2 emitting ultraviolet light, a first substrate 5 on which the semiconductor light-emitting element 2 is mounted, and a second substrate which is arranged on a side of the first substrate opposite to the semiconductor light-emitting element and on which the first substrate 5 is mounted; and adhering an optical member 7 using a resin adhesive 8 to a surface 61 of the second substrate 6 on the first substrate 5 side.

It is thereby possible to suppress degradation of the resin adhesive 8.

The eighth feature of the invention is that, in the seventh feature, the optical member 7 includes a bottom surface 71 adhered via the adhesive 8 to the surface 61 of the second substrate 6 on the first substrate 5 side, and a recessed surface 72 which is recessed from the bottom surface 71, houses the semiconductor light-emitting element 2 and the first substrate 5 and allows entrance of light emitted from the semiconductor light-emitting element 2, and wherein in the adhering the optical member 7 to the surface 61 of the second substrate 6 on the first substrate 5 side, positioning of the optical member 7 relative to the semiconductor light-emitting element 2 and the first substrate 5 is performed by fitting the semiconductor light-emitting element 2 and the first substrate 5 to the recessed surface 72.

It is thereby possible to easily perform positioning of the optical member 7 relative to the semiconductor light-emitting element 2 and the first substrate 5.

Additional Note

Although the embodiments of the invention have been described, the invention according to claims is not to be limited to the embodiments described above. Further, please note that not all combinations of the features described in the embodiments are necessary to solve the problem of the invention. In addition, the invention can be appropriately modified and implemented without departing from the gist thereof.

1. A light-emitting device, comprising:
a semiconductor light-emitting element emitting ultraviolet light;
a first substrate on which the semiconductor light-emitting element is mounted;
a second substrate which is arranged on a side of the first substrate opposite to the semiconductor light-emitting element and on which the first substrate is mounted; and
an optical member adhered using a resin adhesive to a surface of the second substrate on the first substrate side.

2. The light-emitting device according to claim 1, wherein when viewed in a cross section parallel to an alignment direction of the semiconductor light-emitting element, the first substrate and the second substrate,
at least a portion of the adhesive is arranged in a region between a first-side intersection point and a second-side intersection point on the surface of the second substrate on the first substrate side,
where an end portion of the semiconductor light-emitting element on the side opposite to the second substrate and also on a first side, which is one side in an orthogonal direction orthogonal to the alignment direction, is defined as a first-side element end portion,
an end portion of the first substrate on the side opposite to the second substrate and also on the first side in the orthogonal direction is defined as a first-side substrate end portion,
a point at which a first-side imaginary straight line connecting the first-side element end portion and the first-side substrate end portion intersects the surface of the second substrate on the first substrate side is defined as the first-side intersection point,
an end portion of the semiconductor light-emitting element on the side opposite to the second substrate and also on a second side, which is opposite to the first side in the orthogonal direction, is defined as a second-side element end portion,
an end portion of the first substrate on the side opposite to the second substrate and also on the second side in the orthogonal direction is defined as a second-side substrate end portion, and
a point at which a second-side imaginary straight line connecting the second-side element end portion and the second-side substrate end portion intersects the surface of the second substrate on the first substrate side is defined as the second-side intersection point.

3. The light-emitting device according to claim 1, wherein the optical member comprises a bottom surface adhered via the adhesive to the surface of the second substrate on the first substrate side, and a recessed surface which is recessed from the bottom surface, houses the semiconductor light-emitting element and the first substrate and allows entrance of light emitted from the semiconductor light-emitting element.

4. The light-emitting device according to claim 3, wherein when viewed in a cross section parallel to an alignment direction of the semiconductor light-emitting element, the first substrate and the second substrate, the recessed surface comprises a portion that extends inward in a direction orthogonal to the alignment direction as a distance from the second substrate in the alignment direction increases.

5. The light-emitting device according to claim 3, wherein the recessed surface is formed along a side surface of the first substrate.

6. The light-emitting device according to claim 1, wherein the adhesive comprises an ultraviolet absorber that absorbs ultraviolet rays.

7. A method for manufacturing a light-emitting device, comprising:
assembling a semiconductor light-emitting element emitting ultraviolet light, a first substrate on which the semiconductor light-emitting element is mounted, and a second substrate which is arranged on a side of the first substrate opposite to the semiconductor light-emitting element and on which the first substrate is mounted; and
adhering an optical member using a resin adhesive to a surface of the second substrate on the first substrate side.

8. The method according to claim 7, wherein the optical member comprises a bottom surface adhered via the adhesive to the surface of the second substrate on the first substrate side, and a recessed surface which is recessed from the bottom surface, houses the semiconductor light-emitting element and the first substrate and allows entrance of light emitted from the semiconductor light-emitting element, and wherein in the adhering the optical member to the surface of the second substrate on the first substrate side, positioning of the optical member relative to the semiconductor light-emitting element and the first substrate is performed by fitting the semiconductor light-emitting element and the first substrate to the recessed surface.
